(19) United States
(12) Patent Application Publication
(10) Pub. No.: US 2026/0260039 A1
(43) Pub. Date: Sep. 3, 2026

(54) SYSTEMS AND METHODS FOR GEOLOGIC PRODUCTION WORKFLOW

(71) Applicant: Schlumberger Technology Corporation, Sugar Land, TX (US)

(72) Inventors: Zhun Li, Houston, TX (US); Atul Laxman Katole, Houston, TX (US); Rajarshi Banerjee, Houston, TX (US); Manas Kumar Koley, Houston, TX (US); Tao Zhao, Houston, TX (US)

(21) Appl. No.: 19/068,645

(22) Filed: Mar. 3, 2025

(51) Int. Cl. G06F 30/27

(52) U.S. Cl. CPC G06F 30/27

(57) ABSTRACT

Systems and methods for geologic production workflow are provided. A method includes: generating a forecast for extracting materials from a geological formation, including: providing data inputs including: a production history, a list of relevant features, and a list of categorical features, preparing data for a machine-learning model, the preparing data including: normalizing, sorting, and splitting the data inputs into a training dataset and a testing dataset, and providing normalization parameters, training a model using the training dataset, generating loss value and weight values, testing the trained model using the testing dataset and the generated loss and weight values, applying a final weight to the tested data, combining the weighted tested data with the normalization parameters and a prediction input to form a prediction, and generating a prediction output for each material, and operating equipment to extract the one or more materials in accordance with the generated forecast.

### TECHNICAL FIELD

This disclosure generally relates to systems and methods for geologic production workflow.

### BACKGROUND

To forecast production for a well, e.g., oil, gas, and/or water, certain information is required, such as geologic formation, location, reservoir property, and completion parameters, etc. If available, previous production history is also highly relevant, as well production typically follows a known decline pattern.

Traditional workflow for production forecasting primarily relies on decline curve analysis (DCA). DCA is a curve-fitting process that requires the matching of production history of current well, without considering production history of other vicinity wells across the basin. Furthermore, the DCA process does not take well information beyond production history, such as geological information and completion information, as input. In unconventional resource plays, in which the economical production life cycle is much shorter than in conventional reservoirs, there is a need to have reliable production forecast as early as possible, with limited production history. Such a scenario is very challenging for traditional DCA workflows.

Accordingly, there is a need for systems and methods for horizontal wells for in geologic production workflow. There is also a need for systems and methods for production forecasting and decline curve analysis. Moreover, there is a need to provide production forecast on planned wells without production history, for which the traditional DCA workflows are not capable of providing any prediction.

### SUMMARY

This disclosure pertains to systems and methods for geologic production workflow.

A first aspect of this disclosure pertains to a method, including: generating a forecast for extracting one or more materials from a geological formation, the generating including: providing data inputs including: a production history, a list of relevant features, and a list of categorical features, preparing data for a machine-learning model using the production history, the list of relevant features, and the list of categorical features, the preparing data including: normalizing the data inputs, sorting the data inputs, splitting the data inputs into a training dataset and a testing dataset according to a predefined split ratio, and providing normalization parameters, training a model using the training dataset, generating at least one loss value and at least one weight value for the model, testing the trained model using the testing dataset and the generated at least one loss value and at least one weight value, applying a final weight to the tested data, combining the weighted tested data with the normalization parameters and a prediction input to form a prediction, and generating a prediction output for each of the one or more materials, and operating equipment at the geological formation to extract the one or more materials in accordance with the generated forecast.

A second aspect of this disclosure pertains to the method of the first aspect, wherein the model includes a decline curve estimation operation.

A third aspect of this disclosure pertains to the method of the second aspect, wherein the model includes an encoder including: a first positional encoding configured to inject information about a relative position of a first portion of the data inputs in a first sequence, a first multi-head self-attention mechanism configured to: receive a first query matrix, a first key matrix, and a first value matrix from the first positional encoding, and calculate first respective attention scores, a first feed-forward network including two linear layers with a rectified linear unit (ReLU) activation therebetween, the first feed-forward network being configured to process the representations produced by the self-attention, a first layer normalization and residual connection for the first multi-head self-attention mechanism configured to stabilize the training, and a second layer normalization and residual connection for the first feed-forward network configured to further stabilize the training.

A fourth aspect of this disclosure pertains to the method of the third aspect, wherein the model further includes a decoder including: a second positional encoding configured to inject information about a relative position of a second portion of the data inputs in a second sequence, a masked second multi-head self-attention mechanism configured to: receive a second query matrix, a second key matrix, and a second value matrix from the second positional encoding, and calculate respective second attention scores, a third multi-head self-attention mechanism configured to: receive a third value matrix and a third key matrix from the encoder, receive a third query matrix from the masked second multi-head self-attention mechanism, and calculate respective third attention scores, a second feed-forward network including two linear layers with a ReLU activation therebetween, the second feed-forward network being configured to process the representations produced by the third multi-head self-attention mechanism, a third layer normalization and residual connection for the masked second multi-head self-attention mechanism configured to further stabilize the training, and a fourth layer normalization and residual connection for the third multi-head self-attention mechanism configured to further stabilize the training, and a fourth layer normalization and residual connection for the second feed-forward network configured to further stabilize the training.

A fifth aspect of this disclosure pertains to the method of the fourth aspect, wherein the decoder further includes: a linear transformation module, and a softmax module.

A sixth aspect of this disclosure pertains to the method of the first aspect, wherein the data inputs include: static features including at least one of: a well location, a formation type, a well depth, or one or more hydraulic fracturing parameters, and time-series features including at least one of: an oil production rate, a gas production rate, or a water production rate.

A seventh aspect of this disclosure pertains to the method of the sixth aspect, wherein each of the time-series features is used as a respective channel for an encoder input.

A eighth aspect of this disclosure pertains to the method of the seventh aspect, wherein decoder channels respectively corresponding to the channels for the encoder input are set to zero (0).

A ninth aspect of this disclosure pertains to the method of the first aspect, wherein the at least one loss value is calculated according to at least one of: a mean square error (MSE) equation or a mean absolute error (MAE) equation.

A tenth aspect of this disclosure pertains to the method of the first aspect, wherein the one or more materials include at least one of: oil, gas, or water.

An eleventh aspect of this disclosure pertains to a system, including: one or more processors, a non-transitory computer-readable medium storing instructions that, when executed, cause the one or more processors to: generate a forecast for extracting one or more materials from a geological formation, including: providing data inputs including: a production history, a list of relevant features, and a list of categorical features, preparing data for a machine-learning model using the production history, the list of relevant features, and the list of categorical features, the preparing data including: normalizing the data inputs, sorting the data inputs, splitting the data inputs into a training dataset and a testing dataset according to a predefined split ratio, and providing normalization parameters, training a model using the training dataset, generating at least one loss value and at least one weight value for the model, testing the trained model using the testing dataset and the generated at least one loss value and at least one weight value, applying a final weight to the tested data, combining the weighted tested data with the normalization parameters and a prediction input to form a prediction, and generating a prediction output for each of the one or more materials, and operating equipment at the geological formation to extract the one or more materials in accordance with the generated forecast.

A twelfth aspect of this disclosure pertains to the system of the eleventh aspect, wherein the model includes a decline curve estimation operation.

A thirteenth aspect of this disclosure pertains to the system of the twelfth aspect, wherein the model includes an encoder including: a first positional encoding configured to inject information about a relative position of a first portion of the data inputs in a first sequence, a first multi-head self-attention mechanism configured to: receive a first query matrix, a first key matrix, and a first value matrix from the first positional encoding, and calculate first respective attention scores, a first feed-forward network including two linear layers with a rectified linear unit (ReLU) activation therebetween, the first feed-forward network being configured to process the representations produced by the self-attention, a first layer normalization and residual connection for the first multi-head self-attention mechanism configured to stabilize the training, and a second layer normalization and residual connection for the first feed-forward network configured to further stabilize the training.

A fourteenth aspect of this disclosure pertains to the system of the thirteenth aspect, wherein the model further includes a decoder including: a second positional encoding configured to inject information about a relative position of a second portion of the data inputs in a second sequence, a masked second multi-head self-attention mechanism configured to: receive a second query matrix, a second key matrix, and a second value matrix from the second positional encoding, and calculate respective second attention scores, a third multi-head self-attention mechanism configured to: receive a third value matrix and a third key matrix from the encoder, receive a third query matrix from the masked second multi-head self-attention mechanism, and calculate respective third attention scores, a second feed-forward network including two linear layers with a ReLU activation therebetween, the second feed-forward network being configured to process the representations produced by the third multi-head self-attention mechanism, a third layer normalization and residual connection for the masked second multi-head self-attention mechanism configured to further stabilize the training, and a fourth layer normalization and residual connection for the third multi-head self-attention mechanism configured to further stabilize the training, and a fourth layer normalization and residual connection for the second feed-forward network configured to further stabilize the training.

A fifteenth aspect of this disclosure pertains to the system of the fourteenth aspect, wherein the decoder further includes: a linear transformation module, and a softmax module.

A sixteenth aspect of this disclosure pertains to the system of the eleventh aspect, wherein the data inputs include: static features including at least one of: a well location, a formation type, a well depth, or one or more hydraulic fracturing parameters, and time-series features including at least one of: an oil production rate, a gas production rate, or a water production rate.

A seventeenth aspect of this disclosure pertains to the system of the sixteenth aspect, wherein each of the time-series features is used as a respective channel for an encoder input.

An eighteenth aspect of this disclosure pertains to the system of the seventeenth aspect, wherein decoder channels respectively corresponding to the channels for the encoder input are set to zero (0).

A nineteenth aspect of this disclosure pertains to the system of the eleventh aspect, wherein the at least one loss value is calculated according to at least one of: a mean square error (MSE) equation or a mean absolute error (MAE) equation.

A twentieth aspect of this disclosure pertains to the system of the eleventh aspect, wherein the one or more materials include at least one of: oil, gas, or water.

This summary is provided to introduce a selection of concepts that are further described below in the detailed description. This summary is not intended to identify key or essential features of the claimed subject matter, nor is it intended to be used as an aid in limiting the scope of the claimed subject matter.

Additional features and advantages of embodiments of the disclosure will be set forth in the description which follows, and in part will be obvious from the description, or may be learned by the practice of such embodiments. The features and advantages of such embodiments may be realized and obtained by means of the instruments and combinations particularly pointed out in the appended claims. These and other features will become more fully apparent from the following description and appended claims or may be learned by the practice of such embodiments as set forth hereinafter.

### BRIEF DESCRIPTION OF DRAWINGS

To describe the manner in which the above-recited and other features of the disclosure can be obtained, a more particular description will be rendered by reference to specific implementations thereof which are illustrated in the appended drawings. For better understanding, the like elements have been designated by like reference numbers throughout the various accompanying figures. While some of the drawings may be schematic or exaggerated representations of concepts, at least some of the drawings may be drawn to scale. Understanding that the drawings depict some example implementations, the implementations will be described and explained with additional specificity and detail through the use of the accompanying drawings in which:

FIG. 1 is a diagram of a workflow for a model configuration according to an example embodiment of the present disclosure.

FIG. 2 is an enlarged version of the output predictions graph in FIG. 1.

FIG. 3 is a flow diagram of a transformer model architecture showing sequence lengths of an encoder input and a decoder input and output according to an example embodiment of the present disclosure.

FIG. 4 is a flow diagram of an encoder for a transformer model architecture according to an example embodiment of the present disclosure.

FIG. 5 is a table illustrating a data format according to an example embodiment of the present disclosure.

FIG. 6 is a set of graphs showing experimental results of inputs and outputs from a same well.

FIG. 7 is flow diagram of a workflow according to an example embodiment of the present disclosure.

FIG. 8 illustrates certain components that may be included within a computer system according to an example embodiment of the present disclosure.

Before explaining the disclosed embodiment of this disclosure in detail, it is to be understood that the disclosure is not limited in its application to the details of the particular arrangement shown, as the disclosure is capable of other embodiments. Example embodiments are illustrated in referenced figures of the drawings. It is intended that the embodiments and figures disclosed herein are to be considered illustrative rather than limiting. Also, the terminology used herein is for the purpose of description and not of limitation.

### DETAILED DESCRIPTION

While the subject disclosure applies to embodiments in many different forms, there are shown in the drawings and will be described in detail herein specific embodiments with the understanding that the present disclosure is an example of the principles of the embodiments. It is not intended to limit the disclosure to the specific illustrated embodiments. The features of the disclosure disclosed herein in the description, drawings, and claims can be significant, both individually and in any desired combinations, for the operation of the disclosure in its various embodiments. Features from one embodiment can be used in other embodiments of the disclosure. In the description of the drawings, like reference numerals refer to like elements.

Example embodiment of the present disclosure may provide a deep learning model to conduct production forecasting and decline curve analysis on wells (e.g., oil, gas, or water) with and without a known production history. The deep learning model may be trained based on production data from a large number of wells across multiple basins. The wells may be horizontal wells, although embodiments are not limited thereto.

To incorporate both well information and production history from vicinity wells, example embodiments of the present disclosure may provide a machine learning model that will take available information, such as production history, geological information, and completion information, as training input. Then the trained machine learning model may be used to forecast production on target wells. Example embodiments may provide an approach to include production history and well information of the target well and other wells across or beyond the basin into the algorithm to obtain a more robust and accurate forecast, using limited to no production history, for both existing wells and new and/or planned wells. Example embodiments can be applied as production forecasting tool to predict well production at various locations where the training dataset has coverage.

A workflow according to an example embodiment may take account of well information and production history of wells across or beyond a geological formation, e.g., a basin, for production forecasting. Aside from production history, an example workflow may consider the well information to generate production forecasts. Therefore, an example process according to an embodiment can provide a robust and accurate forecast, using limited to no production history, for both existing wells and new and/or planned wells. Example embodiments may provide more reasonable forecasts by incorporating data from different aspects, and data from different locations, for both existing wells and new and/or planned wells. An example embodiment may provide a pre-trained basin-wide production forecast machine learning model to be used for a production forecast. An example embodiment may also implement the described process to train a machine learning production forecast model using a new dataset to generate production forecasts. Downhole equipment at the wellsite may be operated in accordance with the generated forecast, for example, upon receipt of an operation signal, e.g., to produce the forecasted materials, e.g., oil, gas, and/or water according to the generated forecast.

In addition to well forecasts and planning for operations at a wellsite (e.g., drilling or exploration operations), a machine learning model trained in accordance with an example embodiment may be used, for example, for well surveillance. For example, data relating to actual production from the well may be compared (e.g., superimposed) with a forecast to determine whether the well is behaving as expected or behaving properly. If the actual well data sufficiently matches the forecast model, then it may be presumed that the model is correct and that the well is performing properly. If not, then the well may be re-fractured and/or a pump may be put in the well, e.g., to help pump out material, for example, oil, gas, or water.

Decline curve analysis (DCA) is a graphical method used to analyze decreasing production rates and predict future performance of oil and gas wells. Production rates decline over time due to factors like reservoir pressure loss or changes in the relative volumes of produced fluids. The DCA concept involves fitting a line through historical performance data and presuming this trend will continue.

Example embodiments may train a combination of four deep learning models that take static input (e.g., formation information, location information, completion information, etc.) and if available, time dependent input (e.g., previous oil, gas, and water production), and may predict future production. Models that only take static input may be designed for forecasting new well production. Models that take both static input and time dependent input may be designed for production forecasting of existing wells. The output of the models can be configured to be either time series of future production, or decline curve parameters, such as qᵢ, b, and dᵢ from an Arps decline curve. For example, the four models may include the following configurations:
1. For a new (or planned) well, generate time series production forecast;
2. For a new (or planned) well, generate decline curve parameters;
3. For an existing well, generate time series production forecast; and
4. For an existing well, generate decline curve parameters.

The models may take an arbitrary length (e.g., time period) of production history as input and generate arbitrary length of production forecasting as output. However, for practical purposes and computational efficiency, in the experiments described herein, the maximum length of input time series was set to be sixty (60) months, and the maximum length of output was set to be 24 months. If the production history of a well was longer than five (5) years, the most recent 5 years of production history were taken as input to the models in the experiments.

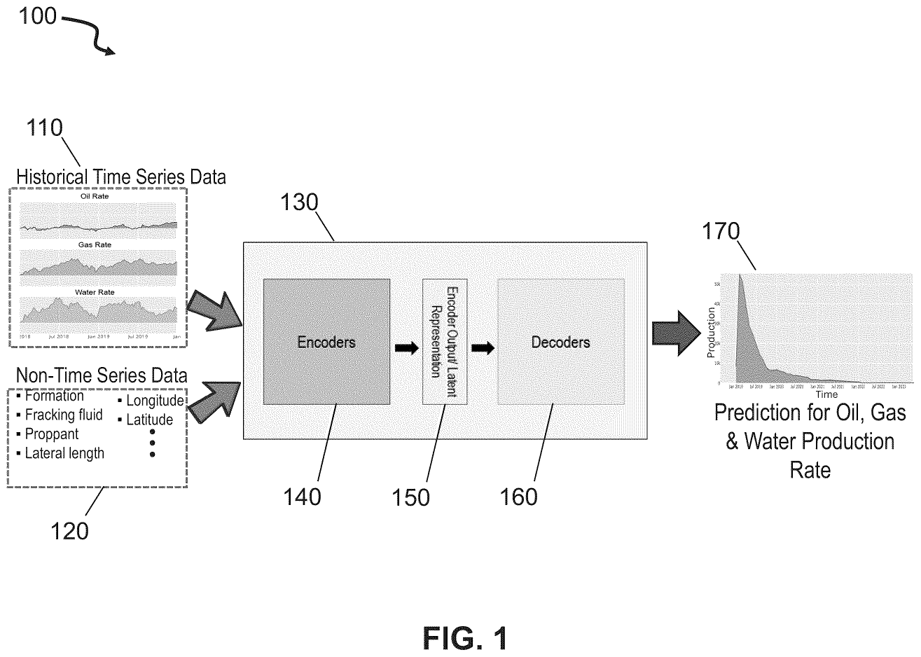

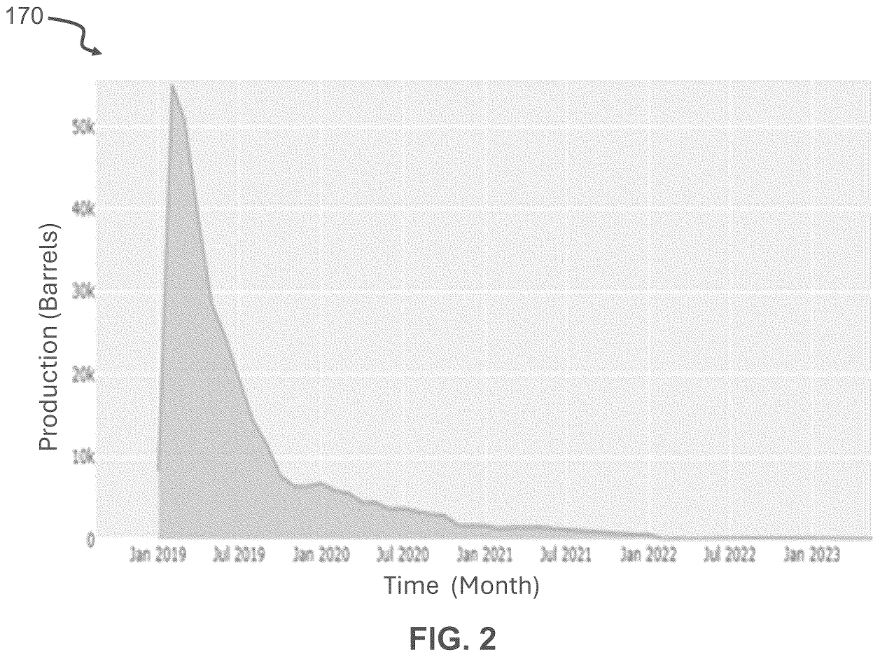

FIG. 1 is a diagram of a workflow for a model configuration according to an example embodiment of the present disclosure. FIG. 2 is an enlarged version of the output predictions graph in FIG. 1.

An example method may include three phases, e.g., (1) data preparation, (2) training and testing, and (3) model deployment and prediction. FIG. 1 illustrates an example configuration of inputs and outputs of a model in accordance with an example embodiment of the present disclosure.

FIG. 1 illustrates a configuration of an example of a model 100 that may be used for production forecasting and decline curve analysis. Inputs to the model may include historical time series data 110 and non-time series data 120. The historical time series data 110 may include, for example, past production rates for oil, gas, and water. The non-time series data 120 may include, for example, formation, longitude, latitude, fracking fluid, proppant, and lateral length. These features may be used with the historical time series data 110 to improve the accuracy of the predictions. The types of data listed herein are not intended to be limiting.

A processing block 130 may include one or more encoders 140, an encoder output/latent representation block 150, and one or more decoders 160. The one or more encoders 140 may process the input data and transform it into a format suitable for the model. The encoder output/latent representation block 150 may be an output from the one or more encoders 140, which may be a latent representation of the input data, and may serve as an intermediate step before the data is passed to the one or more decoders 160. The one or more decoders 160 may take the latent representation from the encoder output/latent representation block 150 and may generate output predictions 170. The one or more decoders 160 may be responsible for converting the encoded data back into a human-understandable format, such as future production rates.

The output predictions 170 may include a prediction for an oil, gas, and water production rate. This may be the final output of the model. In the illustrated example, the output predictions 170 is provided as a graph that provides the forecasted production rates for oil, gas, and water, although other forecasts may be output, depending on the input data parameters and desired output fields. The FIG. 1 example shows the output predictions 170 as an experimental result of a prediction over a five-year time period (e.g., 2019 through 2023), which is enlarged to show detail in FIG. 2.

### Transformer Architecture

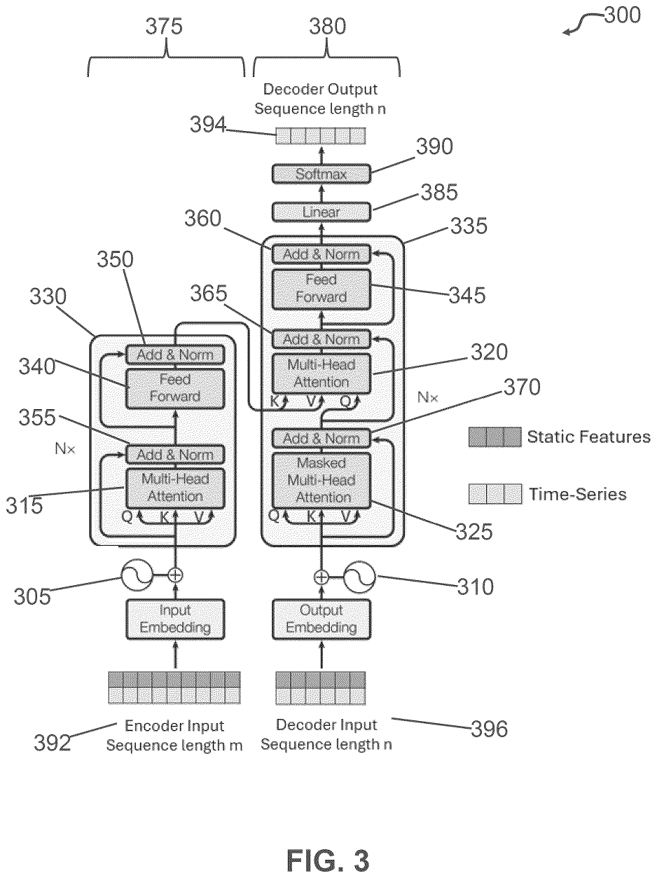

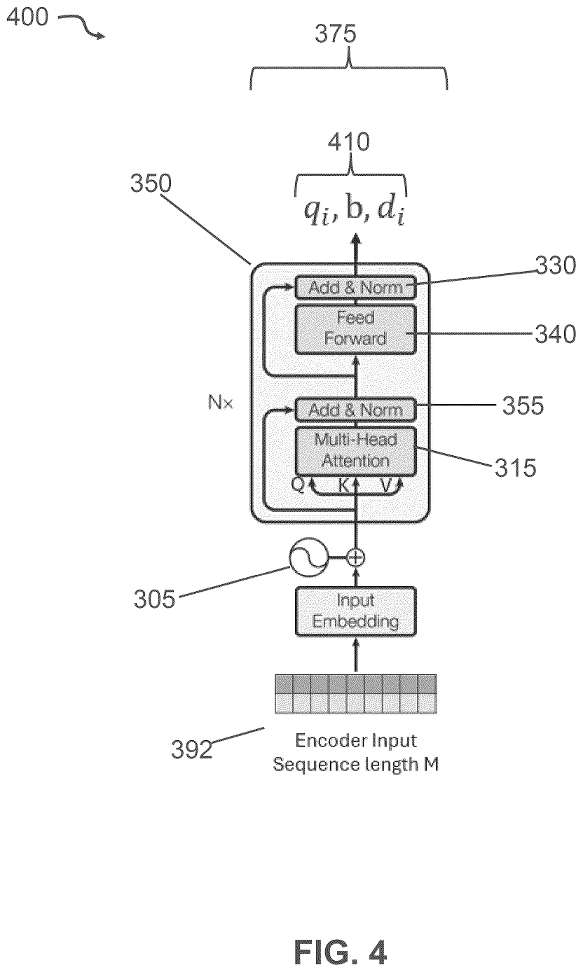

FIG. 3 is a flow diagram of a transformer model architecture showing sequence lengths of an encoder input and a decoder input and output according to an example embodiment of the present disclosure. FIG. 4 is a flow diagram of an encoder for a transformer model architecture according to an example embodiment of the present disclosure.

Existing deep learning methods for time-series forecasting have primarily involved recurrent neural network (RNN) architecture, which is a type of neural network that process a sequence of inputs and retains its state while processing the next sequence of inputs. However, employment of RNN causes issues, such as vanishing or exploding gradients, which pose significant challenges in training RNNs and in processing long sequences.

To prevent the issues with RNNs, example embodiments of the present disclosure may employ a transformer model with an attention layer as a deep learning model in an example workflow. The transformer model, introduced by Vaswani, A. et al. (“Attention is all you need,” Advances in Neural Information Processing Systems, 2017, pp. 5998-6008), revolutionized natural language processing and deep learning by replacing recurrent or convolutional neural network architectures with self-attention and cross attention mechanisms. Transformer architecture is very efficient in sequence-to-sequence modeling application in natural language processing, e.g., next sentence prediction or translation. “Tokens” are words, character sets, or combinations of words and punctuation that are used by large language models (LLMs) into which to decompose text, and it literally represents a certain element in a sequence. In a workflow in accordance with an example embodiment, a transformer model may be used to map from production history as a input sequence to production forecast as output sequence, and use “token” to refer to feature data, e.g. production rate, in a time-step.

A description of transformer model architecture and some components for an example transformer model 300, in accordance with an example embodiment of the present disclosure, is shown in FIG. 3.

### Positional Encoding

Unlike RNNs, transformers do not have a built-in sense of sequence order. To provide a sequence order, the transformer adds positional encodings 305, 310 to the input embeddings. The positional encodings 305, 310, which may be based on sine and cosine functions, may inject information about the relative position of each token in the sequence.

### Self-Attention Mechanism

A core idea behind the transformer model is a self-attention mechanism, which allows the model to focus on different parts of the input sequence simultaneously. The self-attention mechanism 315, 320, 325, computes a set of attention weights for each token in the input sequence, allowing the model to attend to other tokens when producing a representation for a specific token.

Self-attentions may be computed using three matrices:
1. Query (Q)
2. Key (K)
3. Value (V)

These matrices may be learned and used to calculate attention scores between tokens. Each token is transformed into a weighted sum of all other tokens based on these scores, allowing the model to capture contextual dependencies.

### Multi-Head Attention

Instead of a single attention mechanism, the transformer model employed in accordance with an example embodiment may use multi-head attention (315, 320, 325), which applies multiple attention functions in parallel. Each head processes a different aspect of the sequence, allowing the model to capture various relationships. Multi-head attention may be particularly useful for capturing nuanced relationships by creating multiple attention scores, which are then combined to produce richer representations.

### Feed-Forward Neural Network

Each layer (Nx) 330, 335 in the transformer may have a fully connected feed-forward network 340, 345 applied to each position separately and identically. Each feed-forward network 340, 345 may include two linear layers with a rectified linear unit (ReLU) activation in between. The feed-forward networks 340, 345 may further process the representations produced by the self-attention mechanisms 315, 320, 325.

### Layer Normalization and Residual Connections

The transformer model may use layer normalization and residual (e.g., skip) connections 350, 355, 360, 365, 370 around both the attention and feed-forward layers, which may help in stabilizing the training process and enabling deeper architectures.

### Encoder-Decoder Architecture

The transformer model may include at least one encoder 375 and at least one decoder 380. The encoder may include a stack of identical layers 330 (Nx), each containing a multi-head self-attention mechanism 315 and a feed-forward network 340. The decoder 380 may be similar to the encoder 375, but may include an additional layer of multi-head attention 320, 325 that may be focused on the encoder's output to allow for alignment between input and output sequences. A a linear transformation function 385 and/or a softmax function 390 may be applied to generate an output for the decoder 380.

### Process

The architecture of a transformer model in accordance with an example embodiment may include at least one encoder and at least one decoder, e.g., encoder 375 and decoder 380 of FIG. 3. There may be separate encoder input(s) and decoder input(s). The decoder output may be the final output of the model. For example, as illustrated in FIG. 3, the sequence length of a decoder input 392 may be equal to the sequence length of a decoder output 394. Here, ‘n’ represents the sequence length of the decoder input and output, and ‘m’ represents the sequence length of the encoder input. The sequence length m of an encoder input 396 is not necessarily equal to n. Therefore, the production forecasting task may be formulated as, given a production history with m time steps, predicting production over the next n time steps. For example, if xₜ, t=−m, −m−1, . . . , −1, represents an input production history, then the neural network model may output yₜ,=0, 1, . . . , n as a production forecast.

The encoder input 392 may include both static features and time-series features. Static features may include data such as well location, formation, well depth, hydraulic fracturing parameters, etc. Time-series features may include oil, gas, and water production rates. Each static feature may take up one channel of the encoder input 392, and the same static feature value may be applied on each position of the encoder input sequence. The oil, gas, and water production rates may take up another three (3) channels of encoder input 392, for example. The decoder input 396 may have the same structure as the encoder input 392, except that the time-series channels may all be set as zeros (0). In other words, the decoder 380 may not have any production data input. A primary purpose of the decoder 380 may be to configure the spatial relationships of forecasting sequence by adding positional encoding to the decoder input 396.

An output of the network may be the production forecast, for example, for the upcoming n months. Let yₜ* represent a t^{th} time step of a ground truth production. The loss function may be calculated as a mean square error (MSE)(Equation 1) or a mean absolute error (MAE)(Equation 2) between network output and ground truth production forecast, as shown below in Equations 1 and 2.

$$Loss = {\sum }_{t = 0}^{n} {( {y}_{t} - {y}_{t}^{*} )}^{2} \qquad [ Equation 1 ]$$

$$Loss = {\sum }_{t = 0}^{n} {\vert {y}_{t} - {y}_{t}^{*} \vert}^{2} \qquad [ Equation 2 ]$$

The choice of loss function may depend on data quality. The mean square error loss function is commonly understood to be less robust to outliers. When the trend of production decline is affected by operations, such as shut-in, and the dataset presents a lot of outliers, the mean absolute error should be used as the loss function, and vice versa.

Another important feature of the transformer model architecture is that, both sequence lengths m and n can vary during inference. This can be attributed to that, during attention calculation, Q, K, V are calculated on each element of the sequence, and this operation does not require a fixed-length input. However, input and output sequence length should be fixed during training because training samples in each batch should share the same dimensions. The following approaches may be employed to enable the model to handle variable input and output lengths during inference and to share the same batch dimensions during training, and were used during experimentation using a model in accordance with an example embodiment:
1. Use fixed input and output sequence lengths and set these two lengths with values that are large enough to enable the model to have enough dataset coverage during training phase. In an experiment using a model in accordance with an example embodiment, the input sequence length was set to be 60 months, and the output sequence length was set to be 24 months.
2. If the production history of a well is longer than 60 months, the most recent 60 months of production history may be input to the models. If the production history is shorter than 60 months, the elements of sequence before production starts may be set to zeros.
3. If the sequence length of the production forecast target is less than 24 months, the elements of ground truth sequence after the last valid production data point may be set to zeros (0). In addition, the final loss may be multiplied by a binary mask Mᵢ with the same shape as the output sequence. Mₜ=1 if a t^{th} time step is within the period that a valid ground truth target covers, and Mₜ=0 if a t^{th} time step is outside (or beyond) that period. The new loss function may become Equation 3 below.

$$Loss = {\sum }_{t = 0}^{n} {( {y}_{t} - {y}_{t}^{*} )}^{2} {M}_{t} \qquad [ Equation 3 ]$$

In addition to generating the prediction and matching the ground truth during the forecasting period, the model may predict the production during part of the latest input period, may match this part of input data within the same period, and may include this error into the loss function. By employing this approach, not only can the model be trained to predict what it has never seen, but also the model may be trained to predict part of what the model has seen from input. This approach may help stabilize the model with dataset that contains a large amount of outliers. Let ‘l’ represent the length of latest input production to be included in the loss function. The loss function can be formulated as in Equation 4 below.

$$Loss = {\sum }_{t = - 1}^{- l} {( {y}_{t} - {x}_{t} )}^{2} + {\sum }_{t = 0}^{n} {( {y}_{t} - {y}_{t}^{*} )}^{2} {M}_{t} \qquad [ Equation 4 ]$$

### New Well Forecast

When performing a production forecast for a new (or planned) well, there would be no available production history. To address this issue, all of the input production time series may be set as zeros (0), and the same model architecture and the same input and output structures may be maintained as for an existing well with a production history.

### Decline Curve Parameters Estimation

A common use case for production forecasting is to estimate the decline curve parameters, such as qᵢ, b, dᵢ from the Arps decline curve. The Arps decline curve applies the equation for a hyperbola to define three general equations to model production declines. To locate a hyperbola line on an x-y coordinate plane, qᵢ is a starting point on a y-axis, b is a degree of curvature of the line, and dᵢ is an initial decline rate. In an example embodiment, the decoder may be removed from the architecture, and the encoder may be retained. By applying one linear layer to the original output of the encoder, the output of qᵢ, b, dᵢ, may be provided as shown in FIG. 4. FIG. 4 illustrates a model 400 for an encoder, e.g., the encoder 375 of FIG. 3, with decline curve parameters 410. As the model will directly output a production forecast, the loss function may be reformulated as in Equation 5 below. A conversion factor of 30.4 may be included if ‘t’ represents a time period of a month.

$$Loss = {\sum }_{t = 0}^{n} {( \frac{{q}_{i}}{{( 1 + 30.4 b {d}_{i} t )}^{\frac{1}{b}}} - {y}_{t}^{*} )}^{2} {M}_{t} \qquad [ Equation 5 ]$$

### Data Preparation

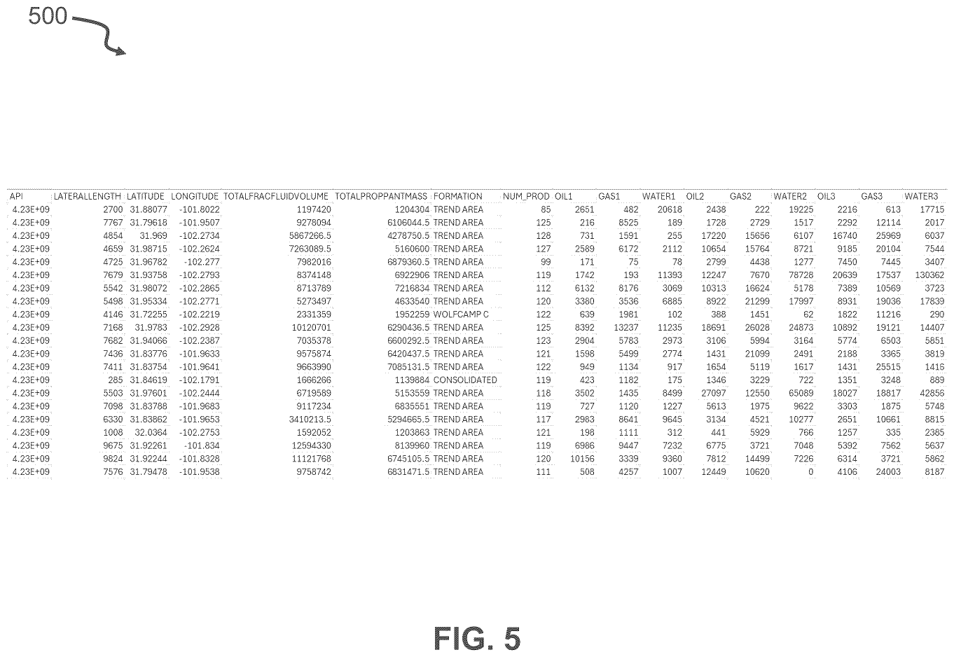

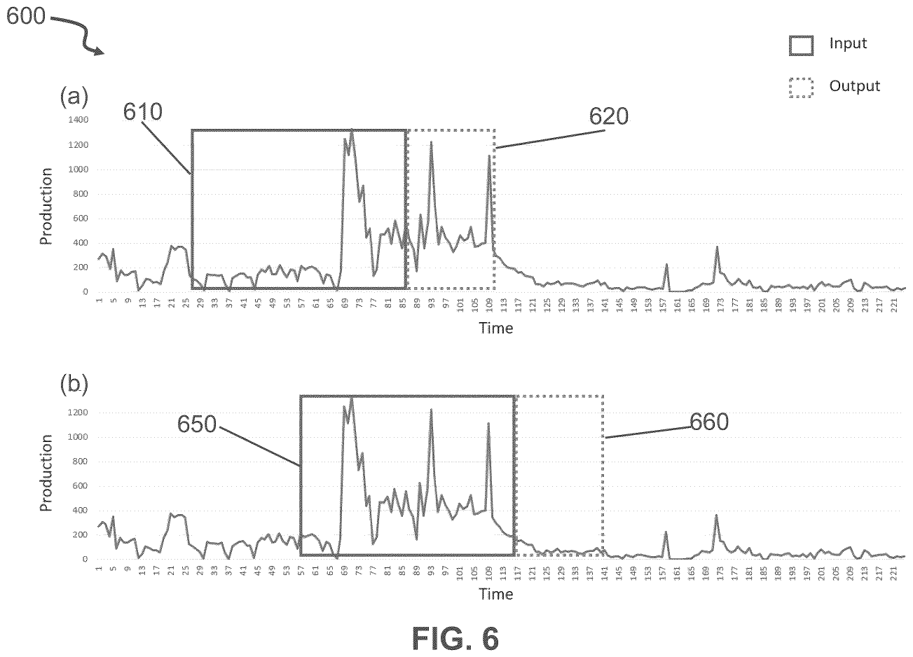

FIG. 5 is a table illustrating a data format according to an example embodiment of the present disclosure. FIG. 6 is a set of graphs showing experimental results of inputs and outputs from a same well.

During the data preparation phase, production data and well information from producing well dataset may be collected. Well data and geological information can be selected as features input for the model. In this workflow the model may be designed to perform both training and prediction. A user can train the model using their own wells' production data, e.g., by preparing their own training dataset and specifying their own non-time-series features. For example, the user may have the flexibility to specify the dataset to include any parameter, such as well location, formation name, fracking fluid volume, proppant amount, etc. The user can also include other non-time-series parameters into the features. For example, to prepare the dataset for training and testing, the user may feed a file into the program, e.g., a .csv file or pandas Dataframe with the format as illustrated in the FIG. 5 table 500. The table 500 may be provided as a file, for example, .csv file, which may be a “master_csv.csv” file. In an experiment, a public monthly dataset of about 3,000 wells from a county was collected to train the model and demonstrate this workflow.

In one example, a “master_csv.csv” file may be created to comply with the following format:
Each row corresponds to data for an individual well;
Each column represents a different feature that might be included in the training, testing, and prediction of the deep learning model;
A column labeled “OIL1” indicates the first month oil production rate. “OIL2” indicates the second month oil production rate, and so on. “GAS1” indicates the first month of gas production rate. “WATER1” indicates the first month of water production, and so on for “GAS2”, “WATER2”, etc.
A column labeled “NUM_PROD” indicates the number of months that production consists of. The data in this column should be correct. For example, if the value for NUM_PROD is 10, the program will keep reading data from columns “OIL1”, “GAS1” and “WATER1” all the way up to “OIL10”, “GAS10” and “WATER10”, and then stop reading production data, even if there might be columns such as “OIL11”, “GAS100” and “WATER500”, which may indicate there are wells with longer production history. However, the user should ensure that for certain NUM_PROD, there are corresponding oil, gas, and water columns in the “master_csv.csv” file, otherwise the program will report error that these columns cannot be loaded.

In this example, in addition to the “master_csv.csv” file, the user may feed the following parameters to the program to prepare the dataset:
A list of the names of all the features to be used in the model. All the features in this list, plus oil, gas, and water will be used as features in the deep learning model. Columns in the “master_csv.csv” file that do not show up in this list, e.g., a Python list, will not be used in the program. This provides flexibility for the user to investigate different combinations of features from a big .csv file that may include many feature columns. The user should ensure that for each feature name in the Python list, there is a corresponding column in the .csv file with the same column name.
A list of the names of all the categorical features. The program will treat the rest of features as numerical features. This categorical feature list should be a subset of the previous all-feature list.

After feeding the “master_csv.csv” file, the full feature list, and the categorical feature list into the program, the whole dataset will be normalized, shuffled, and split into training dataset and testing dataset, e.g., with a split ratio of 70:30 (or 70/30).

To allow the deep learning model to see more variations of the dataset and be able to forecast with various lengths of production history, a random time-shift may be employed. During this process, the production history of a well may be randomly shifted, e.g., to left or right, for example, by various numbers of months, to allow the model to see different segments of production history as input. FIG. 6 shows two examples of randomly selected input/output sections from the same well. For example, in the top graph (a), the production history of an input box 610 may be shifted to the production history of an output box 620. As another example, in the bottom graph (b), the production history of an input box 650 may be shifted to the production history of an output box 660.

### Training and Testing

Training of the deep learning model may include updating the deep learning network weights to reduce or minimize the value of a pre-defined loss function. In this case, the loss function may be defined as the mean square error (MSE) between the ground truth oil, gas, water rates versus the predicted oil, gas, water rates. Considering the volatile nature of the real production data, a moving average with window size of 3-5 months may be applied to the ground truth data. The loss function may be the mean square error between the forecast and the moving average version of the ground truth data. The weight of the model may be saved regularly, for example, to a specified directory of a storage device, e.g., a memory, e.g., an electronic storage disk, hard drive, cloud storage, flash memory, etc.

Testing of the model may be started, for example, as soon as the training start and training weight is written to the storage device. A purpose of performing testing may be to avoid overfitting and promote model generalization. The final training weight may be selected when testing loss reaches a minimum and/or when training loss reaches certain threshold(s).

### Prediction

To forecast the production of a well, a user may need to feed the corresponding features of that well into the trained model. The input features may be prepared as a file, e.g., a .csv file or panda Dataframe, for example, with exactly the same format as the previously-mentioned “master_csv.csv” file. Each line of the file, e.g., .csv file or Dataframe, may represent input data for an individual well. If there are multiple lines in the file, e.g., .csv file, the forecast may be performed on each well (e.g., each line) sequentially.

Various lengths of oil, gas, and water production history can be defined in the file, e.g., .csv file. If there is no production data, column NUM_PROD should be set to be zero (0), and the model will perform the task as new well production forecast.

### Overall Workflow

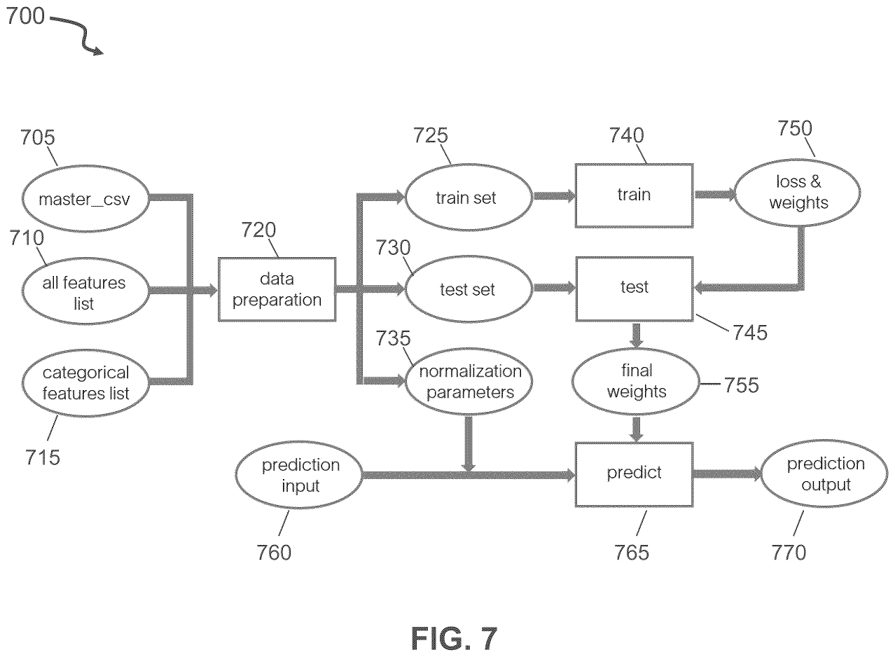

FIG. 7 is flow diagram of a workflow according to an example embodiment of the present disclosure.

An example of an overall workflow 700 is illustrated in FIG. 7. Inputs, e.g., of a production history 705, e.g., a master_csv file, a list 710 of all relevant features, e.g., a list of the names of all the features to be used in the model, and a list 715 of categorical features, e.g., a list of the names of all the categorical features to be used in the model, may be provided for data preparation 720. The data preparation 720 may provide a training data set 725, a testing data set 730 and a set of normalization parameters 735. The training data set 725 may be used to train 740 a model, and the testing data set 730 may be used to test 745 the model using calculated loss and weight values 750 that are generated during the training. For example, the training dataset 725 and the testing dataset 730 may be split from the prepared data 720 according to a predefined ratio, e.g., 70% of the prepared data 720 may be used for the training dataset 725, and 30% of the prepared data 720 may be used for the testing dataset 730. Final weight(s) 755 may be applied to the tested data, which may be combined with the normalization parameters 735 and a prediction input 760 to form a prediction 755. Finally, a prediction output 770 may be produced for the various products, e.g., oil, gas, and/or water.

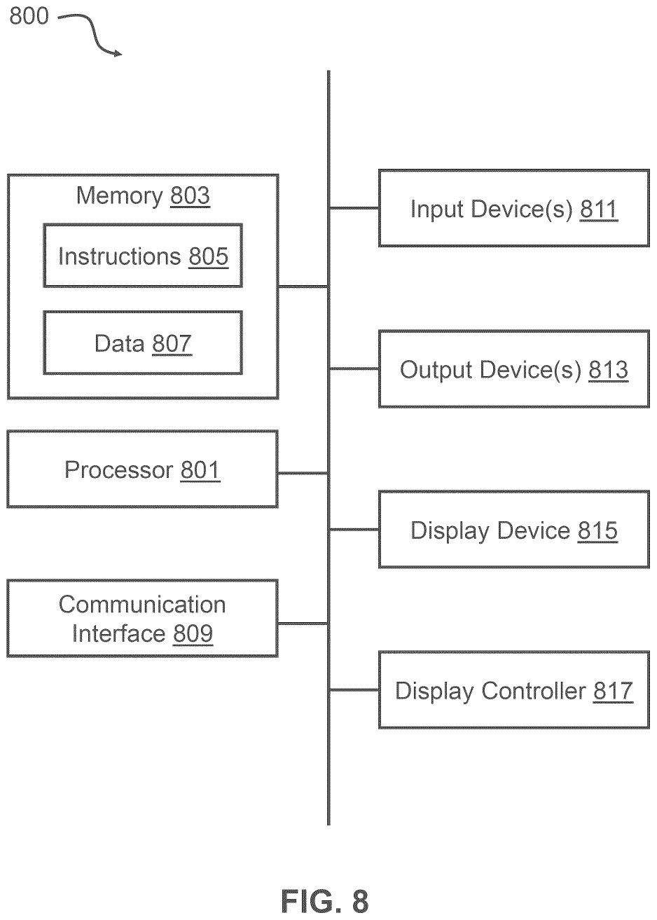

FIG. 8 illustrates certain components that may be included within a computer system according to an example embodiment of the present disclosure.

FIG. 8 illustrates certain components that may be included within a computer system 800, which may be used to control features according to embodiments of the present disclosure, such as the features discussed with reference to FIGS. 1-7. One or more computer systems 800 may be used to implement the various devices, components, and systems described herein.

The computer system 800 includes a processor 801. The processor 801 may be a single processor or may include multiple processors. The processor 801 may be a general-purpose single- or multi-chip microprocessor (e.g., an Advanced RISC (Reduced Instruction Set Computer) Machine (ARM)), a special-purpose microprocessor (e.g., a digital signal processor (DSP)), a microcontroller, a programmable gate array, etc. The processor 801 may be referred to as a central processing unit (CPU). Although just a single processor 801 is shown in the computer system 800 of FIG. 8, in an alternative configuration, a combination of processors (e.g., an ARM and DSP) could be used. In one or more embodiments, the computer system 800 further includes one or more graphics processing units (GPUs), which can provide processing services related to both entity classification and graph generation.

The computer system 800 also includes memory 803 in electronic communication with the processor 801. The memory 803 may be any electronic component capable of storing electronic information. For example, the memory 803 may be embodied as random access memory (RAM), read-only memory (ROM), magnetic disk storage media, optical storage media, flash memory devices in RAM, on-board memory included with the processor, erasable programmable read-only memory (EPROM), electrically erasable programmable read-only memory (EEPROM) memory, registers, and so forth, including combinations thereof.

Instructions 805 and data 807 may be stored in the memory 803. The instructions 805 may be executable by the processor 801 to implement some or all of the functionality disclosed herein. Executing the instructions 805 may involve the use of the data 807 that is stored in the memory 803. Any of the various examples of modules and components described herein may be implemented, partially or wholly, as instructions 805 stored in memory 803 and executed by the processor 801. Any of the various examples of data described herein may be among the data 807 that is stored in memory 803 and used during execution of the instructions 805 by the processor 801.

A computer system 800 may also include one or more communication interfaces 809 for communicating with other electronic devices. The communication interface(s) 809 may be based on wired communication technology, wireless communication technology, or both. Some examples of communication interfaces 809 include a Universal Serial Bus (USB), an Ethernet adapter, a wireless adapter that operates in accordance with an Institute of Electrical and Electronics Engineers (IEEE) 802.11 wireless communication protocol, a Bluetooth® wireless communication adapter, and an infrared (IR) communication port.

A computer system 800 may also include one or more input devices 811 and one or more output devices 813. Some examples of input devices 811 include a keyboard, mouse, microphone, remote control device, button, joystick, trackball, touchpad, and lightpen. Some examples of output devices 813 include a speaker and a printer. One specific type of output device that is typically included in a computer system 800 is a display device 815. Display devices 815 used with embodiments disclosed herein may utilize any suitable image projection technology, such as liquid crystal display (LCD), light-emitting diode (LED), gas plasma, electroluminescence, or the like. A display controller 817 may also be provided, for converting data 807 stored in the memory 803 into text, graphics, and/or moving images (as appropriate) shown on the display device 815.

The various components of the computer system 800 may be coupled together by one or more buses, which may include a power bus, a control signal bus, a status signal bus, a data bus, etc. For the sake of clarity, the various buses are illustrated in FIG. 8 as a bus system 819.

Following are sections in accordance with at least one embodiment of the present disclosure:

Clause 1: A method, including: generating a forecast for extracting one or more materials from a geological formation, the generating including: providing data inputs including: a production history, a list of relevant features, and a list of categorical features, preparing data for a machine-learning model using the production history, the list of relevant features, and the list of categorical features, the preparing data including: normalizing the data inputs, sorting the data inputs, splitting the data inputs into a training dataset and a testing dataset according to a predefined split ratio, and providing normalization parameters, training a model using the training dataset, generating at least one loss value and at least one weight value for the model, testing the trained model using the testing dataset and the generated at least one loss value and at least one weight value, applying a final weight to the tested data, combining the weighted tested data with the normalization parameters and a prediction input to form a prediction, and generating a prediction output for each of the one or more materials, and operating equipment at the geological formation to extract the one or more materials in accordance with the generated forecast.

Clause 2: The method of Clause 1, wherein the model includes a decline curve estimation operation.

Clause 3: The method of Clause 2, wherein the model includes an encoder including: a first positional encoding configured to inject information about a relative position of a first portion of the data inputs in a first sequence, a first multi-head self-attention mechanism configured to: receive a first query matrix, a first key matrix, and a first value matrix from the first positional encoding, and calculate first respective attention scores, a first feed-forward network including two linear layers with a rectified linear unit (ReLU) activation therebetween, the first feed-forward network being configured to process the representations produced by the self-attention, a first layer normalization and residual connection for the first multi-head self-attention mechanism configured to stabilize the training, and a second layer normalization and residual connection for the first feed-forward network configured to further stabilize the training.

Clause 4: The method of Clause 3, wherein the model further includes a decoder including: a second positional encoding configured to inject information about a relative position of a second portion of the data inputs in a second sequence, a masked second multi-head self-attention mechanism configured to: receive a second query matrix, a second key matrix, and a second value matrix from the second positional encoding, and calculate respective second attention scores, a third multi-head self-attention mechanism configured to: receive a third value matrix and a third key matrix from the encoder, receive a third query matrix from the masked second multi-head self-attention mechanism, and calculate respective third attention scores, a second feed-forward network including two linear layers with a ReLU activation therebetween, the second feed-forward network being configured to process the representations produced by the third multi-head self-attention mechanism, a third layer normalization and residual connection for the masked second multi-head self-attention mechanism configured to further stabilize the training, and a fourth layer normalization and residual connection for the third multi-head self-attention mechanism configured to further stabilize the training, and a fourth layer normalization and residual connection for the second feed-forward network configured to further stabilize the training.

Clause 5: The method of Clause 4, wherein the decoder further includes: a linear transformation module, and a softmax module.

Clause 6: The method of Clause 1, wherein the data inputs include: static features including at least one of: a well location, a formation type, a well depth, or one or more hydraulic fracturing parameters, and time-series features including at least one of: an oil production rate, a gas production rate, or a water production rate.

Clause 7: The method of Clause 6, wherein each of the time-series features is used as a respective channel for an encoder input.

Clause 8: The method of Clause 7, wherein decoder channels respectively corresponding to the channels for the encoder input are set to zero (0).

Clause 9: The method of Clause 1, wherein the at least one loss value is calculated according to at least one of: a mean square error (MSE) equation or a mean absolute error (MAE) equation.

Clause 10: The method of Clause 1, wherein the one or more materials include at least one of: oil, gas, or water.

Clause 11: A system, including: one or more processors, a non-transitory computer-readable medium storing instructions that, when executed, cause the one or more processors to: generate a forecast for extracting one or more materials from a geological formation, including: providing data inputs including: a production history, a list of relevant features, and a list of categorical features, preparing data for a machine-learning model using the production history, the list of relevant features, and the list of categorical features, the preparing data including: normalizing the data inputs, sorting the data inputs, splitting the data inputs into a training dataset and a testing dataset according to a predefined split ratio, and providing normalization parameters, training a model using the training dataset, generating at least one loss value and at least one weight value for the model, testing the trained model using the testing dataset and the generated at least one loss value and at least one weight value, applying a final weight to the tested data, combining the weighted tested data with the normalization parameters and a prediction input to form a prediction, and generating a prediction output for each of the one or more materials, and operating equipment at the geological formation to extract the one or more materials in accordance with the generated forecast.

Clause 12: The system of Clause 11, wherein the model includes a decline curve estimation operation.

Clause 13: The system of Clause 12, wherein the model includes an encoder including: a first positional encoding configured to inject information about a relative position of a first portion of the data inputs in a first sequence, a first multi-head self-attention mechanism configured to: receive a first query matrix, a first key matrix, and a first value matrix from the first positional encoding, and calculate first respective attention scores, a first feed-forward network including two linear layers with a rectified linear unit (ReLU) activation therebetween, the first feed-forward network being configured to process the representations produced by the self-attention, a first layer normalization and residual connection for the first multi-head self-attention mechanism configured to stabilize the training, and a second layer normalization and residual connection for the first feed-forward network configured to further stabilize the training.

Clause 14: The system of Clause 13, wherein the model further includes a decoder including: a second positional encoding configured to inject information about a relative position of a second portion of the data inputs in a second sequence, a masked second multi-head self-attention mechanism configured to: receive a second query matrix, a second key matrix, and a second value matrix from the second positional encoding, and calculate respective second attention scores, a third multi-head self-attention mechanism configured to: receive a third value matrix and a third key matrix from the encoder, receive a third query matrix from the masked second multi-head self-attention mechanism, and calculate respective third attention scores, a second feed-forward network including two linear layers with a ReLU activation therebetween, the second feed-forward network being configured to process the representations produced by the third multi-head self-attention mechanism, a third layer normalization and residual connection for the masked second multi-head self-attention mechanism configured to further stabilize the training, and a fourth layer normalization and residual connection for the third multi-head self-attention mechanism configured to further stabilize the training, and a fourth layer normalization and residual connection for the second feed-forward network configured to further stabilize the training.

Clause 15: The system of Clause 14, wherein the decoder further includes: a linear transformation module, and a softmax module.

Clause 16: The system of Clause 11, wherein the data inputs include: static features including at least one of: a well location, a formation type, a well depth, or one or more hydraulic fracturing parameters, and time-series features including at least one of: an oil production rate, a gas production rate, or a water production rate.

Clause 17: The system of Clause 16, wherein each of the time-series features is used as a respective channel for an encoder input.

Clause 18: The system of Clause 17, wherein decoder channels respectively corresponding to the channels for the encoder input are set to zero (0).

Clause 19: The system of Clause 11, wherein the at least one loss value is calculated according to at least one of: a mean square error (MSE) equation or a mean absolute error (MAE) equation.

Clause 20: The system of Clause 11, wherein the one or more materials include at least one of: oil, gas, or water.

Systems and software, e.g., implemented on a non-transitory computer-readable medium, for performing the methods discussed herein are also within the scope of embodiments of the present disclosure.

Embodiments of the present disclosure may thus utilize a special purpose or general-purpose computing system including computer hardware, such as, for example, one or more processors and system memory. Embodiments within the scope of the present disclosure also include physical and other computer-readable media for carrying or storing computer-executable instructions and/or data structures, including applications, tables, data, libraries, or other modules used to execute particular functions or direct selection or execution of other modules. Such computer-readable media can be any available media that can be accessed by a general purpose or special purpose computer system. Computer-readable media that store computer-executable instructions (or software instructions) are physical storage media. Computer-readable media that carry computer-executable instructions are transmission media. Thus, by way of example, and not limitation, embodiments of the present disclosure can include at least two distinctly different kinds of computer-readable media, namely physical storage media or transmission media. Combinations of physical storage media and transmission media should also be included within the scope of computer-readable media.

Both physical storage media and transmission media may be used temporarily store or carry, software instructions in the form of computer readable program code that allows performance of embodiments of the present disclosure. Physical storage media may further be used to persistently or permanently store such software instructions. Examples of physical storage media include physical memory (e.g., RAM, ROM, EPROM, EEPROM, etc.), optical disk storage (e.g., CD, DVD, HDDVD, Blu-ray, etc.), storage devices (e.g., magnetic disk storage, tape storage, diskette, etc.), flash or other solid-state storage or memory, or any other non-transmission medium which can be used to store program code in the form of computer-executable instructions or data structures and which can be accessed by a general purpose or special purpose computer, whether such program code is stored as or in software, hardware, firmware, or combinations thereof.

A “network” or “communications network” may generally be defined as one or more data links that enable the transport of electronic data between computer systems and/or modules, engines, and/or other electronic devices. When information is transferred or provided over a communication network or another communications connection (either hardwired, wireless, or a combination of hardwired or wireless) to a computing device, the computing device properly views the connection as a transmission medium. Transmission media can include a communication network and/or data links, carrier waves, wireless signals, and the like, which can be used to carry desired program or template code means or instructions in the form of computer-executable instructions or data structures and which can be accessed by a general purpose or special purpose computer.

Further, upon reaching various computer system components, program code in the form of computer-executable instructions or data structures can be transferred automatically or manually from transmission media to physical storage media (or vice versa). For example, computer-executable instructions or data structures received over a network or data link can be buffered in memory (e.g., RAM) within a network interface module (NIC), and then eventually transferred to computer system RAM and/or to less volatile physical storage media at a computer system. Thus, it should be understood that physical storage media can be included in computer system components that also (or even primarily) utilize transmission media.

One or more specific embodiments of the present disclosure are described herein. These described embodiments are examples of the presently disclosed techniques. Additionally, in an effort to provide a concise description of these embodiments, not all features of an actual embodiment may be described in the specification. It should be appreciated that in the development of any such actual implementation, as in any engineering or design project, numerous embodiment-specific decisions will be made to achieve the developers' specific goals, such as compliance with system-related and business-related constraints, which may vary from one embodiment to another. Moreover, it should be appreciated that such a development effort might be complex and time consuming, but would nevertheless be a routine undertaking of design, fabrication, and manufacture for those of ordinary skill having the benefit of this disclosure.

The articles “a,” “an,” and “the” are intended to mean that there are one or more of the elements in the preceding descriptions. The terms “comprising,” “including,” and “having” are intended to be inclusive and mean that there may be additional elements other than the listed elements. Additionally, it should be understood that references to “one embodiment” or “an embodiment” of the present disclosure are not intended to be interpreted as excluding the existence of additional embodiments that also incorporate the recited features. For example, any element described in relation to an embodiment herein may be combinable with any element of any other embodiment described herein. Numbers, percentages, ratios, or other values stated herein are intended to include that value, and also other values that are “about” or “approximately” the stated value, as would be appreciated by one of ordinary skill in the art encompassed by embodiments of the present disclosure. A stated value should therefore be interpreted broadly enough to encompass values that are at least close enough to the stated value to perform a desired function or achieve a desired result. The stated values include at least the variation to be expected in a suitable manufacturing or production process, and may include values that are within 5%, within 1%, within 0.1%, or within 0.01% of a stated value.

A person having ordinary skill in the art should realize in view of the present disclosure that equivalent constructions do not depart from the spirit and scope of the present disclosure, and that various changes, substitutions, and alterations may be made to embodiments disclosed herein without departing from the spirit and scope of the present disclosure. Equivalent constructions, including functional “means-plus-function” clauses are intended to cover the structures described herein as performing the recited function, including both structural equivalents that operate in the same manner, and equivalent structures that provide the same function. It is the express intention of the applicant not to invoke means-plus-function or other functional claiming for any claim except for those in which the words ‘means for’ appear together with an associated function. Each addition, deletion, and modification to the embodiments that falls within the meaning and scope of the claims is to be embraced by the claims.

The terms “approximately,” “about,” and “substantially” as used herein represent an amount close to the stated amount that still performs a desired function or achieves a desired result. For example, the terms “approximately,” “about,” and “substantially” may refer to an amount that is within less than 5% of, within less than 1% of, within less than 0.1% of, and within less than 0.01% of a stated amount. Further, it should be understood that any directions or reference frames in the preceding description are merely relative directions or movements. For example, any references to “up” and “down” or “above” or “below” are merely descriptive of the relative position or movement of the related elements.

The present disclosure may be embodied in other specific forms without departing from its spirit or characteristics. The described embodiments are to be considered as illustrative and not restrictive. The scope of the disclosure is, therefore, indicated by the appended claims rather than by the foregoing description. Changes that come within the meaning and range of equivalency of the claims are to be embraced within their scope.

What is claimed is:

1. A method, comprising:
generating a forecast for extracting one or more materials from a geological formation, the generating comprising:
providing data inputs comprising:
a production history;
a list of relevant features; and
a list of categorical features;
preparing data for a machine-learning model using the production history, the list of relevant features, and the list of categorical features, the preparing data comprising:
normalizing the data inputs;
sorting the data inputs;
splitting the data inputs into a training dataset and a testing dataset according to a predefined split ratio; and
providing normalization parameters;
training a model using the training dataset;
generating at least one loss value and at least one weight value for the model;
testing the trained model using the testing dataset and the generated at least one loss value and at least one weight value;
applying a final weight to the tested data;
combining the weighted tested data with the normalization parameters and a prediction input to form a prediction; and
generating a prediction output for each of the one or more materials; and
operating equipment at the geological formation to extract the one or more materials in accordance with the generated forecast.

2. The method of claim 1, wherein the model comprises a decline curve estimation operation.

3. The method of claim 2, wherein the model comprises an encoder comprising:
a first positional encoding configured to inject information about a relative position of a first portion of the data inputs in a first sequence;
a first multi-head self-attention mechanism configured to:
receive a first query matrix, a first key matrix, and a first value matrix from the first positional encoding; and
calculate first respective attention scores;
a first feed-forward network comprising two linear layers with a rectified linear unit (ReLU) activation therebetween, the first feed-forward network being configured to process the representations produced by the self-attention;
a first layer normalization and residual connection for the first multi-head self-attention mechanism configured to stabilize the training; and
a second layer normalization and residual connection for the first feed-forward network configured to further stabilize the training.

4. The method of claim 3, wherein the model further comprises a decoder comprising:
a second positional encoding configured to inject information about a relative position of a second portion of the data inputs in a second sequence;
a masked second multi-head self-attention mechanism configured to:
receive a second query matrix, a second key matrix, and a second value matrix from the second positional encoding; and
calculate respective second attention scores;
a third multi-head self-attention mechanism configured to:
receive a third value matrix and a third key matrix from the encoder;
receive a third query matrix from the masked second multi-head self-attention mechanism; and
calculate respective third attention scores;
a second feed-forward network comprising two linear layers with a ReLU activation therebetween, the second feed-forward network being configured to process the representations produced by the third multi-head self-attention mechanism;
a third layer normalization and residual connection for the masked second multi-head self-attention mechanism configured to further stabilize the training; and
a fourth layer normalization and residual connection for the third multi-head self-attention mechanism configured to further stabilize the training; and
a fourth layer normalization and residual connection for the second feed-forward network configured to further stabilize the training.

5. The method of claim 4, wherein the decoder further comprises:
a linear transformation module; and
a softmax module.

6. The method of claim 1, wherein the data inputs comprise:
static features comprising at least one of: a well location, a formation type, a well depth, or one or more hydraulic fracturing parameters; and
time-series features comprising at least one of: an oil production rate, a gas production rate, or a water production rate.

7. The method of claim 6, wherein each of the time-series features is used as a respective channel for an encoder input.

8. The method of claim 7, wherein decoder channels respectively corresponding to the channels for the encoder input are set to zero (0).

9. The method of claim 1, wherein the at least one loss value is calculated according to at least one of: a mean square error (MSE) equation or a mean absolute error (MAE) equation.

10. The method of claim 1, wherein the one or more materials comprise at least one of: oil, gas, or water.

11. A system, comprising:
one or more processors;
a non-transitory computer-readable medium storing instructions that, when executed, cause the one or more processors to:
generate a forecast for extracting one or more materials from a geological formation, comprising:
providing data inputs comprising:
a production history;
a list of relevant features; and
a list of categorical features;
preparing data for a machine-learning model using the production history, the list of relevant features, and the list of categorical features, the preparing data comprising:
normalizing the data inputs;
sorting the data inputs;
splitting the data inputs into a training dataset and a testing dataset according to a predefined split ratio; and
providing normalization parameters;
training a model using the training dataset;
generating at least one loss value and at least one weight value for the model;
testing the trained model using the testing dataset and the generated at least one loss value and at least one weight value;
applying a final weight to the tested data;
combining the weighted tested data with the normalization parameters and a prediction input to form a prediction; and
generating a prediction output for each of the one or more materials; and
operating equipment at the geological formation to extract the one or more materials in accordance with the generated forecast.

12. The system of claim 11, wherein the model comprises a decline curve estimation operation.

13. The system of claim 12, wherein the model comprises an encoder comprising:
a first positional encoding configured to inject information about a relative position of a first portion of the data inputs in a first sequence;
a first multi-head self-attention mechanism configured to:
receive a first query matrix, a first key matrix, and a first value matrix from the first positional encoding; and
calculate first respective attention scores;
a first feed-forward network comprising two linear layers with a rectified linear unit (ReLU) activation therebetween, the first feed-forward network being configured to process the representations produced by the self-attention;
a first layer normalization and residual connection for the first multi-head self-attention mechanism configured to stabilize the training; and
a second layer normalization and residual connection for the first feed-forward network configured to further stabilize the training.

14. The system of claim 13, wherein the model further comprises a decoder comprising:
a second positional encoding configured to inject information about a relative position of a second portion of the data inputs in a second sequence;
a masked second multi-head self-attention mechanism configured to:
receive a second query matrix, a second key matrix, and a second value matrix from the second positional encoding; and
calculate respective second attention scores;
a third multi-head self-attention mechanism configured to:
receive a third value matrix and a third key matrix from the encoder;
receive a third query matrix from the masked second multi-head self-attention mechanism; and
calculate respective third attention scores;
a second feed-forward network comprising two linear layers with a ReLU activation therebetween, the second feed-forward network being configured to process the representations produced by the third multi-head self-attention mechanism;
a third layer normalization and residual connection for the masked second multi-head self-attention mechanism configured to further stabilize the training; and
a fourth layer normalization and residual connection for the third multi-head self-attention mechanism configured to further stabilize the training; and
a fourth layer normalization and residual connection for the second feed-forward network configured to further stabilize the training.

15. The system of claim 14, wherein the decoder further comprises:
a linear transformation module; and
a softmax module.

16. The system of claim 11, wherein the data inputs comprise:
static features comprising at least one of: a well location, a formation type, a well depth, or one or more hydraulic fracturing parameters; and
time-series features comprising at least one of: an oil production rate, a gas production rate, or a water production rate.

17. The system of claim 16, wherein each of the time-series features is used as a respective channel for an encoder input.

18. The system of claim 17, wherein decoder channels respectively corresponding to the channels for the encoder input are set to zero (0).

19. The system of claim 11, wherein the at least one loss value is calculated according to at least one of: a mean square error (MSE) equation or a mean absolute error (MAE) equation.

20. The system of claim 11, wherein the one or more materials comprise at least one of: oil, gas, or water.
